(19) United States
(12) Patent Application Publication
(10) Pub. No.: US 2026/0128265 A1
(43) Pub. Date: May 7, 2026

(54) SUBSTRATE PROCESSING APPARATUS

(71) Applicant: Samsung Electronics Co., Ltd., Suwon-si (KR)

(72) Inventors: YOUNG-TAE MA, Suwon-si (KR); Young Seok Roh, Suwon-si (KR); Jongduk Suh, Suwon-si (KR)

(73) Assignee: SAMSUNG ELECTRONICS CO., LTD., Suwon-si (KR)

(21) Appl. No.: 19/380,091

(22) Filed: Nov. 5, 2025

(30) Foreign Application Priority Data
Nov. 5, 2024 (KR) 10-2024-0155544

(51) Int. Cl. H01J 37/34; C23C 14/34

(52) U.S. Cl. CPC H01J 37/3447; C23C 14/3407; H01J 37/3426; H01J 2237/3323

(57) ABSTRACT

A substrate processing apparatus may include a chamber, a chuck provided in a lower space of the chamber and set to accommodate a substrate, a plasma electrode provided in an upper space of the chamber and vertically spaced apart from the chuck, a target material provided on a lower surface of the plasma electrode, and a collimator provided between the chuck and the target material, wherein the collimator may include a body defining a plurality of holes, and a source diffusion barrier film provided on a surface of the body and formed of a conductive material.

### CROSS-REFERENCE TO RELATED APPLICATION(S)

This U.S. non-provisional application is based on and claims priority under 35 USC § 119 to Korean Patent Application No. 10-2024-0155544, filed on Nov. 5, 2024, in the Korean Intellectual Property Office, the disclosure of which is herein incorporated by reference in its entirety.

### BACKGROUND

The disclosure relates to a substrate processing apparatus.

Semiconductor devices are manufactured using various semiconductor manufacturing processes. One of the semiconductor manufacturing processes is a deposition process, which includes forming a thin film on a surface of a semiconductor substrate using a physical and/or chemical method. The deposition process includes physical vapor deposition (PVD), chemical vapor deposition (CVD), atomic layer deposition (ALD), etc.

Meanwhile, as semiconductor devices become more highly integrated and miniaturized, a more precise film-forming method is required.

### SUMMARY

Aspects of the disclosure are directed to providing a substrate processing apparatus with improved damage to a base material and deposition precision.

According to an aspect of the disclosure, there is provided a substrate processing apparatus including: a chamber; a chuck provided in the chamber and configured to accommodate a substrate; a plasma electrode provided in the chamber and vertically spaced apart from the chuck; a target material provided on a lower surface of the plasma electrode; and a collimator provided between the chuck and the target material, the collimator including: a body including a plurality of holes; and a source diffusion barrier film provided on a surface of the body and formed of a conductive material.

The source diffusion barrier film may include tantalum (Ta), a tantalum nitride (TaN), titanium (Ti), a titanium nitride (TiN), or a combination thereof.

The body may include aluminum (Al).

The target material may include copper (Cu).

A thickness of the source diffusion barrier film ranges from 100 Å to 5500 Å.

The substrate processing apparatus may further include a bias controller electrically connected to the collimator, the bias controller configured to apply a negative bias voltage to the source diffusion barrier film and the body.

The source diffusion barrier film may include a material having a body-centered cubic (BCC) structure or a hexagonal close-packed (HCP) structure.

The source diffusion barrier film may be formed by a chemical vapor deposition (CVD) method, a physical vapor deposition (PVD) method, or an atomic layer deposition (ALD) method.

According to another aspect of the disclosure, there is provided a substrate processing apparatus including: a chamber; a chuck provided in the chamber and configured to accommodate a substrate; a plasma electrode provided in the chamber and vertically spaced apart from the chuck; a target material on a lower surface of the plasma electrode; and a collimator between the chuck and the target material, the collimator including: a body including a plurality of holes; and a source diffusion barrier film provided on a surface of the body and formed of an insulating material, wherein a thickness of the source diffusion barrier film ranges from 100 Å to 5500 Å.

The source diffusion barrier film may include a metal oxide, a metal sulfide, a metal nitride, a metal fluoride, or a combination thereof.

The body may include a same metal as a metal included in the source diffusion barrier film.

The body may include aluminum (Al), and the source diffusion barrier film may include an aluminum oxide (Al₂O₃).

The source diffusion barrier film may be formed by implanting impurity ions into the body.

The source diffusion barrier film may include a lower portion adjacent to the body and an intermediate portion spaced apart from the lower portion, and wherein an impurity concentration of the intermediate portion of the source diffusion barrier film is higher than an impurity concentration of the lower portion of the source diffusion barrier film.

The source diffusion barrier film may be in an amorphous state.

According to another aspect of the disclosure, there is provided a substrate processing apparatus including: a chamber having an internal space; a chuck provided in the internal space of the chamber; a plasma electrode provided in the internal space of the chamber and spaced apart from the chuck; a target material provided on a lower surface of the plasma electrode and including copper (Cu); a support installed in an intermediate region of the internal space of the chamber; and a collimator mounted on the support and provided between the chuck and the target material, the collimator including: a body may include a plurality of holes, the body including aluminum (Al); and a copper diffusion barrier film formed on a surface of the body.

The substrate processing apparatus may further include a plasma position control module provided on a ceiling portion of the chamber.

The copper diffusion barrier film may be formed of a conductive material.

The copper diffusion barrier film may be formed of an insulating material.

The copper diffusion barrier film may include tantalum (Ta), a tantalum nitride (TaN), titanium (Ti), a titanium nitride (TiN), a metal oxide, a metal sulfide, a metal nitride, a metal fluoride, or a combination thereof.

### BRIEF DESCRIPTION OF DRAWINGS

The above and other aspects, features, and advantages of the embodiments of the disclosure will be more clearly understood from the following detailed description, taken in conjunction with the accompanying drawings.

FIG. 1 is a cross-sectional view of a substrate processing apparatus according to an embodiment of the disclosure.

FIG. 2 is a perspective view of a collimator according to an embodiment of the disclosure.

FIG. 3 is a plan view of a collimator according to an embodiment of the disclosure.

FIG. 4 is a cross-sectional view taken along line A-A′ of FIG. 3.

FIG. 5 is an enlarged view showing region X of FIG. 3.

FIG. 6 is an enlarged view showing region Y of FIG. 4.

FIG. 7 is an impurity concentration graph corresponding to line B-B′ of FIG. 6.

FIGS. 8A and 8B are enlarged views showing a portion of a collimator according to an embodiment of the disclosure and enlarged views corresponding to region Y of FIG. 4.

### DETAILED DESCRIPTION

Hereinafter, embodiments of the disclosure will be described in more detail with reference to the accompanying drawings. As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

According to an embodiment, a substrate processing apparatus may be an apparatus that is provided in a facility that performs various processes required to manufacture a high-performance semiconductor chip on a semiconductor substrate. The substrate processing apparatus may be, for example, a photolithography apparatus, an etching apparatus, an ion implantation apparatus, an oxidation apparatus, a chemical mechanical polishing apparatus, a substrate bonding apparatus, or a deposition apparatus.

The substrate processing apparatus according to an embodiment of the disclosure may be a deposition apparatus for performing a deposition process on a substrate. For example, the substrate processing apparatus may be a physical vapor deposition (PVD) apparatus for performing a PVD process on the substrate. The physical vapor deposition apparatus may be an apparatus that forms a thin film by condensing a solid material on a surface of a substrate through a physical method. The physical method may include, but is not limited to, sputtering or evaporation. According to an embodiment, the substrate may include a semiconductor substrate made of a semiconductor material. However, the disclosure is not limited thereto, and as such, the substrate may include, but is not limited to, a silicon on insulator (SOI) substrate, a metal substrate, a glass substrate, a plastic substrate, etc. The semiconductor substrate may include, but is not limited to, a silicon substrate, a germanium substrate, or a silicon-germanium substrate.

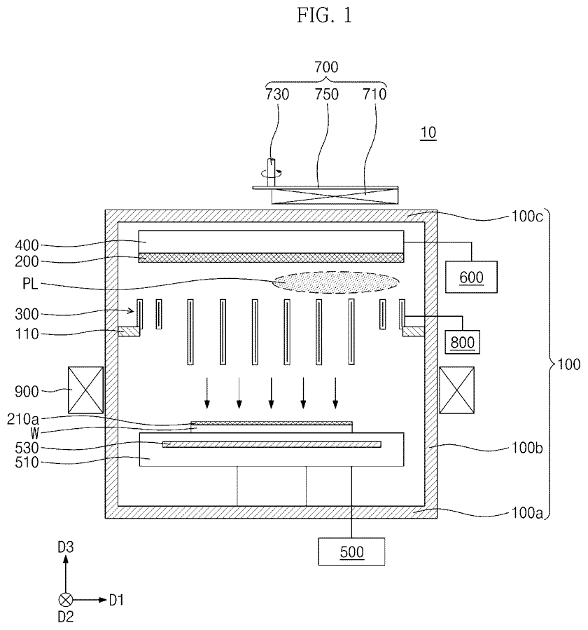

FIG. 1 is a cross-sectional view of a substrate processing apparatus according to an embodiment of the disclosure.

Referring to FIG. 1, according to an embodiment of the disclosure, the substrate processing apparatus 10 may include a chamber 100, a chuck 510, a plasma electrode 400, a target 200, and a collimator 300.

The chamber 100 of the substrate processing apparatus 10 may provide a process space for performing the substrate processing operations. Here, the process space may be an internal space of the chamber 100. For example, a substrate processing process may be performed in the internal space of the chamber 100 through the substrate processing apparatus 10. For example, the substrate processing apparatus 10 may perform the PVD process in the internal space of the chamber 100. The internal space may be isolated from an external space by the chamber 100. The chamber 100 may have a cylindrical shape.

However, this is exemplary, and the chamber 100 may be implemented in various shapes.

The internal space of the chamber 100 may be substantially a vacuum space. The internal space of the chamber 100 may have a pressure of, for example, about 1×10⁻⁸ Torr to about 1×10⁻⁴ Torr.

The chamber 100 may include a bottom portion 100a, a wall portion 100b extending upward from an edge of the bottom portion 100a, and a ceiling portion 100c provided on an upper end of the wall portion 100b. The internal space of the chamber 100 may be a space surrounded by the bottom portion 100a, the wall portion 100b, and the ceiling portion 100c.

For example, the bottom portion 100a of the chamber 100 may be a portion that covers a lower surface of the internal space of the chamber 100. The wall portion 100b may be a portion that extends from the edge of the bottom portion 100a in a third direction D3 perpendicular to a first direction D1 and a second direction D2 and may be a portion that vertically surrounds the internal space of the chamber 100. The ceiling portion 100c may be a portion opposite to the bottom portion 100a of the chamber 100 and may a portion that covers an upper surface of the internal space of the chamber 100.

The chuck 510 may be provided in a lower space of the chamber 100. For example, the chuck 510 may be provided in a lower region of the internal space of the chamber 100. For example, the chuck 510 may be provided above the bottom portion 100a of the chamber 100. The chuck 510 may be set to accommodate a substrate W. For example, the chuck 510 may fix the substrate W while a process is performed. The chuck 510 may have a circular plate shape. The chuck 510 may have a larger area than the substrate W to sufficiently accommodate the substrate W. According to an embodiment, the chuck 510 may be a vacuum chuck that adsorbs the substrate W by vacuum. For example, the chuck 510 may include a plurality of vacuum grooves. However, the chuck 510 is not limited thereto and may be various types of chucks capable of seating the substrate W, for example, an electrostatic chuck, a mechanical chuck, or a magnetic chuck.

According to an embodiment, the chuck 510 may include a heat supply unit 530. The heat supply unit 530 may be set or controlled to heat the substrate W. For example, the heat supply unit 530 may supply heat to the substrate W while the deposition process is performed, thereby assisting in the smooth performance of the deposition process. The heat supply unit 530 may be provided inside the chuck 510. The heat supply unit 530 may have a circular plate shape. However, this is exemplary, and the heat supply unit 530 may be implemented in various shapes. The heat supply unit 530 may have, for example, a line shape extended to have a regular pattern along an upper surface of the chuck 510.

According to an embodiment, a separate heat power supply unit may be connected to the heat supply unit 530. The heat power supply unit may supply power to the heat supply unit 530. The heat supply unit 530 may heat the substrate W using the power.

The heat supply unit 530 may heat the substrate W to, for example, a high temperature of about 300° C. or higher.

According to an embodiment, a stage may be provided in the lower space of the chamber 100. The stage may be provided on a lower surface of the chuck 510 to fix the chuck 510. The stage may have a rectangular plate shape. However, the disclosure is not limited thereto, and as such, the stage may have a different shape. The stage may have a larger area than the chuck 510 to sufficiently fix the chuck 510. The stage may move in the first direction D1, the second direction D2, and the third direction D3. Therefore, the stage may fix the substrate W at a desired position by moving the chuck 510 set to fix the substrate W.

According to an embodiment, a vacuum pump may be provided outside the chamber 100. The vacuum pump may maintain the internal space of the chamber 100 in a high vacuum state by removing gas inside the chamber 100 through a separate pipe connected to the chamber 100. The vacuum pump can increase a deposition rate by decreasing a gas density inside the chamber 100.

According to an embodiment, a gas supply module may be provided outside the chamber 100. The gas supply module may include a separate gas storage tank in which a gas source is stored. Here, the gas source may be, for example, argon (Ar). However, the disclosure is not limited thereto. The gas source stored in the gas storage tank may be injected into the chamber 100 through a separate gas inlet connected to the chamber 100. The gas source injected into the chamber 100 may generate plasma PL by a high voltage applied by the plasma electrode 400.

The plasma electrode 400 may be provided in an upper space of the chamber 100. The plasma electrode 400 may be vertically spaced apart from the chuck 510. For example, the plasma electrode 400 may be provided to be spaced apart from the chuck 510 in the third direction D3 perpendicular to the bottom portion 100a. For example, the plasma electrode 400 may be provided in an upper region of the internal space of the chamber 100.

The plasma electrode 400 may be provided above or over the chuck 510.

The plasma electrode 400 may induce the plasma PL in the chamber 100. For example, the plasma electrode 400 may generate the plasma PL by applying the high voltage in the chamber 100 to emit electrons and to collide the electrons with the gas source injected into the chamber 100. Here, the plasma PL may be, for example, argon (Ar) plasma. The plasma electrode 400 may also control the intensity of the plasma PL by controlling the voltage applied to the internal space of the chamber 100.

According to an embodiment, a DC power supply unit 600 may be connected to the plasma electrode 400. The DC power supply unit 600 may provide direct current power to the plasma electrode 400. For example, the plasma electrode 400 may induce the plasma PL in the chamber 100 using the direct current power provided by the DC power supply unit 600. However, the disclosure is not limited thereto, and in an exemplary embodiment, radio frequency (RF) power may also be provided to the plasma electrode 400.

According to an embodiment, the substrate processing apparatus 10 may further include an RF power supply unit 500. The RF power supply unit 500 may be provided outside the chamber 100 and may be connected to the chuck 510 provided in the lower space of the chamber 100. For example, the RF power supply unit 500 may be connected to the chuck 510 through separate wiring. The RF power supply unit 500 may assist in the generation and maintenance of the plasma PL when the deposition process is performed and may control the energy of electrons and ions by applying a voltage to the substrate W. For example, the RF power supply unit 500 may apply the voltage to the chuck 510 to generate an electromagnetic field on the substrate W and may control ion energy depending on the intensity of a voltage and a frequency. Therefore, the uniformity of the generation of the plasma PL and the deposition process can be maintained.

The target 200 may be mounted on a lower surface of the plasma electrode 400. The target 200 may be provided between the plasma electrode 400 and the chuck 510. The target 200 may include a material to be deposited on the substrate W. The target 200 may include various materials, such as a metal, a ceramic, or an alloy. According to an embodiment, the target 200 may include copper (Cu) or a copper-manganese (CuMn) alloy.

The target 200 may have various shapes. For example, the target 200 may have a circular plate shape with a flat surface. However, the shape of the target 200 is not limited thereto and the target 200 may have an elliptical plate shape, a polygonal plate shape, or a slotted shape with multiple holes.

In an example case in which the PVD process is performed, the plasma PL may be generated between the target 200 and the collimator 300, and source particles may be emitted from the target 200 by the collision of the target 200 and the plasma PL. The source particles may include, but is not limited to, copper ions (Cu²⁺) or copper neutral atoms (Cu). For example, the source particles may be generated from the target 200 by the plasma PL.

Here, the source particles may be a target material to be deposited on the substrate W.

The source particles generated from the target 200 may fall onto the substrate W, thereby forming a thin film 210a on the substrate W. In FIG. 1, a direction in which the source particles move is shown by arrows. Here, a material forming the thin film 210a may be substantially the same as that of the source particles. An amount of the source particles and a thickness of the thin film 210a may increase in proportion to the intensity of the plasma PL. According to an embodiment, the thickness of the thin film 210a according to a position of the substrate W may vary depending on a temperature of the substrate W. In an example case in which the temperature of the substrate W is relatively low, the thickness of the thin film 210a at a central region of the substrate W may be larger than the thickness of the thin film 210a at an edge region of the substrate W. According to an embodiment, the temperature of the substrate W being relatively low may mean that the temperature of the substrate W is less than a reference value. For example, in a case in which the substrate W is at a room temperature (e.g., about 25° C.), the thickness of the thin film 210a at a central region of the substrate W may be larger than the thickness of the thin film 210a at an edge region of the substrate W. This may be because the source particles in the plasma PL are concentrated on the central region of the substrate W. On the other hand, in an example case in which the substrate W is heated to a relatively high temperature (, the thickness of the thin film 210a at the central region of the substrate W may be smaller than the thickness of the thin film 210a at the edge region of the substrate W. According to an embodiment, the temperature of the substrate W being relatively high may mean that the temperature of the substrate W is greater than a reference value. For example, the temperature of the substrate W being relatively high may mean that the temperature is between about 300° C. and about 1000° C.).

The collimator 300 may be provided between the target 200 and the chuck 510. The collimator 300 may be mounted on a support 110 installed in an intermediate region of the internal space of the chamber 100. The support 110 may be provided as a plurality of supports, and the plurality of supports 110 may be provided to face an inner wall of the chamber 100 to fix the collimator 300. The collimator 300 may guide the source particles to travel in direction perpendicular to the substrate W when the deposition process is performed, thereby forming the thin film 210a with a uniform thickness. For example, the collimator 300 may control a flow of the source particles to be in a linear or a straight manner. In addition, the collimator 300 may adsorb and/or filter some of the source particles to control the thickness of the thin film 210a according to the position of the substrate W.

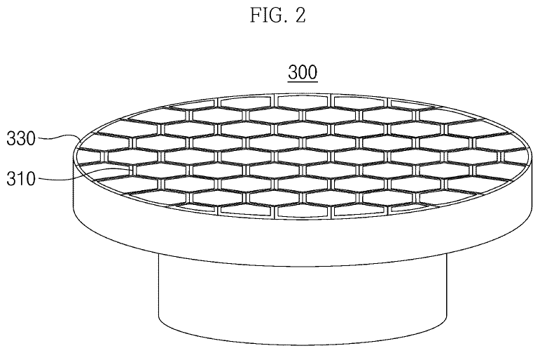

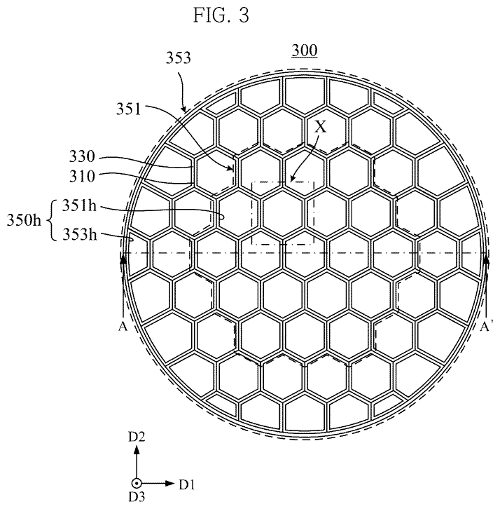

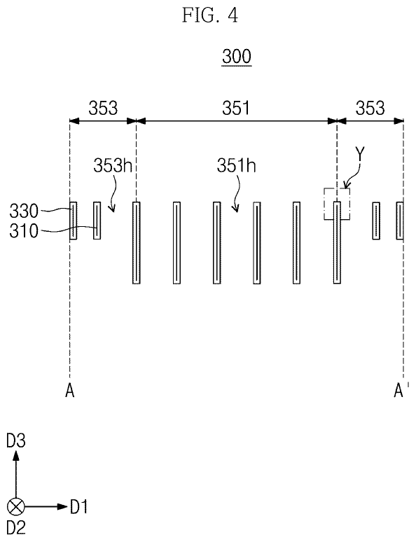

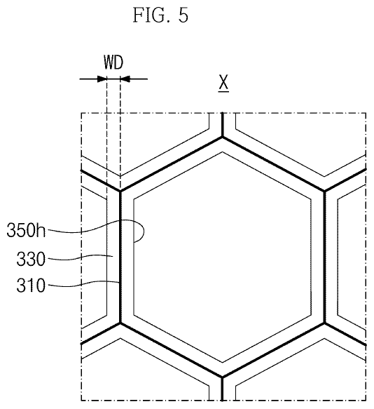

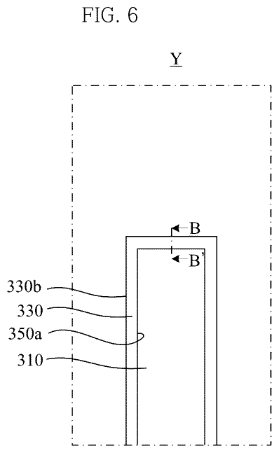

FIG. 2 is a perspective view of the collimator according to an embodiment of the disclosure. FIG. 3 is a plan view of the collimator according to an embodiment of the disclosure. FIG. 4 is a cross-sectional view taken along line A-A′ of FIG. 3. FIG. 5 is an enlarged view showing region X of FIG. 3. FIG. 6 is an enlarged view showing region Y of FIG. 4.

Referring to FIGS. 1 to 6, the collimator 300 may include a body 310 and a plurality of holes 350h defined by the body 310.

The body 310 may form a framework of the collimator 300. The body 310 may correspond to a base material of the collimator 300. For example, the body 310 may form a main body of the collimator 300 and may guide a traveling path of the source particles. For example, the body 310 may guide the source particles in an opposite direction to the third direction D3 when the deposition process is performed. The body 310 may be formed of a durable material in order to withstand an external force or vibration. The body 310 may include a metal different from that of the chamber 100. For example, the body 310 may include aluminum (Al).

The holes 350h may be a space through which the source particles generated from the target 200 may pass toward the substrate W when the deposition process is performed. For example, the body 310 may guide the traveling path of the source particles, and the holes 350h may provide the traveling path of the source particles.

The holes 350h may extend through the body 310. For example, the holes 350h may extend from an upper surface and a lower surface of the body 310 in the third direction D3. Each of the holes 350h may have a hexagonal shape in a plan view. The holes 350h may be arranged in the first direction D1 and the second direction D2 in a plan view. For example, the holes 350h may have a hexagonal honeycomb shape in a plan view. However, the shape of the holes 350h is not limited thereto and the holes 350h may include, for example, a polygon shape or a circular shape other than the hexagonal shape.

The body 310 may have a central region 351 provided at a central portion of the body and an edge region 353 surrounding the central region 351 in a plan view. The holes 350h defined by the central region 351 of the body 310 may be central holes 351h, and the holes 350h defined by the edge region 353 may be edge holes 353h. In an example case in which the holes 350h pass through the upper surface and the lower surface of the body 310, a distance from the upper surface to the lower surface is depths of the holes 350h, as shown in FIG. 4, depths of the central holes 351h may be larger than depths of the edge holes 353h. The central holes 351h may provide main paths through which the source particles can directly pass toward an upper surface of the substrate W, and may assist in uniform deposition by concentrating the traveling direction of the source particles in a direction perpendicular to the substrate W. In addition, the edge holes 353h can prevent the source particles from colliding with each other and scattering toward the periphery of the substrate W.

According to an embodiment, a shape of the collimator 300 may be vary. For example, the collimator 300 may have a shape in which the depths of the central holes 351h and the depths of the edge holes 353h are substantially the same, or a shape in which the depths of the edge holes 353h are larger than the depths of the central holes 351h.

According to an embodiment, a thickness of the body 310 and the depths of the holes 350h may vary. Here, the thickness of the body 310 is a thickness of a body defining the holes 350h in a plan view. In addition, a ratio of area densities of the central holes 351h and the edge holes 353h may vary. The collimator 300 can improve the uniformity of the thickness of the thin film 210a by controlling the thickness of the body 310, the depths of the holes 350h, and the ratio of the area densities of the holes 350h.

According an embodiment of the disclosure, a source diffusion barrier film 330 may be provided on a surface of the body 310. The source diffusion barrier film 330 can prevent the source particles from reacting with the body 310 when the deposition process is performed.

The source diffusion barrier film 330 according to an embodiment of the disclosure can prevent source particles generated from the target 200 from diffusing into the body 310. Therefore, the source diffusion barrier film 330 can prevent damage to the body 310 during a cleaning process of the collimator 300 after the deposition process is performed. As a result, it is possible to prevent an arcing failure that may occur during the deposition process and improve the durability of the collimator 300.

For example, some of the source particles separated from the target 200 may not pass through the holes 350h and may remain on a surface of the collimator 300. The source particles remaining on the surface of the collimator 300 may cause a diffusion reaction into the body 310 to form an alloy. In an example case in which the source particles are copper and the body 310 is made of aluminum, the source particles remaining on the surface of the collimator 300 may form a copper-aluminum (CuAl) alloy with the body 310. After the deposition process is performed, the cleaning process of the collimator 300 may be performed to remove residues remaining on the surface of the collimator 300. During the cleaning process, since the copper-aluminum alloy is removed, the body 310 may be damaged. A damaged portion of the body 310 may gradually become thinner and sharper, and the damaged portion may cause the arcing failure in which the plasma PL is discharged during the deposition process. In other words, the damaged portion gradually becomes thinner and sharper to concentrate an electric field on the damaged portion, thereby causing charges forming the plasma PL to be concentrated on the damaged portion. As a result, the plasma PL may not form source particles by colliding with the target 200 and the plasma PL may be discharged to the damaged portion of the body 310. According to an embodiment, damage to the body 310 can be prevented by forming the source diffusion barrier film 330 on the collimator 300.

In an example case in which the target 200 includes copper, the source diffusion barrier film 330 may also be referred to as a copper diffusion barrier film 330. In other words, the copper diffusion barrier film 330 can prevent copper from diffusing into the body 310.

According to an embodiment, a thickness WD of the source diffusion barrier film 330 may range from about 100 Å to about 5500 Å. The thickness WD of the source diffusion barrier film 330 may range from, for example, about 100 Å to about 4000 Å, about 100 Å to about 3000 Å, or about 100 Å to about 1000 Å.

According to an embodiment, the source diffusion barrier film 330 may include a conductive material. For example, the source diffusion barrier film 330 may include tantalum (Ta), a tantalum nitride (TaN), titanium (Ti), a titanium nitride (TiN), or a combination thereof.

According to an embodiment, the source diffusion barrier film 330 may include an insulating material. The source diffusion barrier film 330 may include, for example, a metal oxide, a metal sulfide, a metal nitride, a metal fluoride, or a combination thereof. The source diffusion barrier film 330 may include, for example, an aluminum oxide (Al₂O₃).

According to an embodiment, a metal included in the source diffusion barrier film 330 may include the same metal as a metal included in the body 310. For example, the body 310 may include aluminum, and the source diffusion barrier film 330 may include an aluminum oxide (Al₂O₃).

According to an embodiment, a material included in the source diffusion barrier film 330 may have a body-centered cubic (BCC) structure or a hexagonal close-packed (HCP) structure. In an example case in which the material forming the source diffusion barrier film 330 has the BCC structure or the HCP structure, the diffusion prevention effect of copper, which has a face-centered cubic (FCC) structure, into the body 310 can be improved.

According to an embodiment, the source diffusion barrier film 330 may be in an amorphous state. In an example case in which the source diffusion barrier film 330 is in an amorphous state, since atoms and/or ions forming the source diffusion barrier film 330 are irregularly distributed, the source particles requires more energy to move. Accordingly, the diffusion prevention effect of the source particles can be further improved.

Referring to FIG. 1, according to an embodiment, the substrate processing apparatus 10 may further include a bias control unit 800. The bias control unit 800 may be connected to a side portion of the collimator 300 through separate wiring. The bias control unit 800 may be electrically connected to the collimator 300 and may be set to apply a negative bias voltage to the source diffusion barrier film 330 and the body 310. According to an embodiment, the bias control unit 800 may use direct current power. The bias control unit 800 may improve the linearity or the straightness of the source particles passing through the holes 350h of the collimator 300 during the deposition process by using the direct current power. Therefore, the bias control unit 800 may improve the uniformity of deposition. In an example case in which the source diffusion barrier film 330 includes the conductive material, since both the body 310 and the source diffusion barrier film 330 include the conductive material, the voltage application efficiency of the bias control unit 800 can be increased.

According to an embodiment, the substrate processing apparatus 10 may further include a plasma position control module 700. The plasma position control module 700 may be provided on the ceiling portion 100c of the chamber 100. The plasma position control module 700 may control the intensity and/or position of the plasma PL using an electric field or a magnetic field when the deposition process is performed. For example, the plasma position control module 700 may include a magnetic body 710, a rotating unit 730, and a base plate 750.

The magnetic body 710 may be provided on a lower surface of the base plate 750. The magnetic body 710 may generate a magnetic field to control the position and movement of the plasma PL when the deposition process is performed. In other words, the magnetic body 710 may guide a path of the plasma PL by using a magnetic force and may concentrate or diffuse a distribution of the plasma PL as needed. The magnetic body 710 may rotate around the rotating unit 730 to increase the uniformity of the magnetic field across a plane of the target 200. For example, the magnetic body 710 may determine a rotation radius of the plasma position control module 700. The magnetic body 710 may have a block shape of a rectangular parallelepiped. However, the shape of the magnetic body 710 is not limited thereto and the magnetic body 710 may have various shapes.

The rotating unit 730 may be connected to a side portion of the base plate 750. The rotating unit 730 may be a portion protruding in the third direction D3 at the center of the ceiling portion 100c of the chamber 100. The rotating unit 730 may be connected to a separate motor to rotate around a rotational axis parallel to the third direction D3. The rotational axis of the rotating unit 730 may be set at the center of the rotating unit. Therefore, the rotating unit 730 may rotate the magnetic body 710. The rotating unit 730 may have a cylindrical or rotating disk shape. However, the shape of the rotating unit 730 is not limited thereto and the rotating unit 730 may have various shapes.

Since the base plate 750 supports the magnetic body 710 and is connected to the rotating unit 730, the base plate 750 may assist in the rotation of the magnetic body 710 by the rotating unit 730. For example, the base plate 750 may more stably support the magnetic body 710 and the rotating unit 730. For example, the base plate 750 may have an upper surface and the lower surface that are parallel to a plane formed by the first and second directions D1 and D2, the rotating unit 730 may be provided at an edge of the upper surface of the base plate 750, and the magnetic body 710 may be provided on the lower surface of the base plate 750. The base plate 750 may be rotated around the rotational axis parallel to the third direction D3 by rotational movement of the rotating unit 730 to rotate the magnetic body 710. The base plate 750 may have a flat plate shape. However, the shape of the base plate 750 is not limited thereto and the base plate 750 may have various shapes.

The plasma position control module 700 may improve the uniformity of deposition by controlling the intensity and/or position of the plasma PL. In addition, the sputtering efficiency in a predetermined region of the target 200 can be increased by causing the plasma PL to be concentrated on a predetermined position. Therefore, the plasma position control module 700 can precisely control the position of the plasma PL and can increase deposition precision.

According to an embodiment, the substrate processing apparatus 10 may further include a magnet 900. The magnet 900 may generate a magnetic field to improve the linear or straight flow of the source particles that have passed through the collimator 300 when the deposition process is performed. For example, the magnet 900 may generate the magnetic field to assist in preventing the source particles passing through the holes 350h of the collimator 300 and falling toward the substrate W from being deviated toward the periphery of the substrate W. The magnet 900 may be provided on a side surface of the outside of the chamber 100. The magnet 900 may be provided at a height between the collimator 300 and the substrate W. The magnet 900 may be provided in a ring shape surrounding a portion of the side surface of the chamber 100. However, the shape of the magnets 900 is not limited thereto. The magnets 900 may also be provided in, for example, a block shape on the side surface of the outside of the chamber 100.

According to an embodiment, a plurality of magnets 900 may be provided on the side surface of the outside of the chamber 100. Therefore, the intensity of the magnetic field formed by the magnets 900 may be increased. As a result, the linear or the straight flow of the source particles can be improved, thereby improving the uniformity of deposition.

Hereinafter, a method for forming the source diffusion barrier film 330 will be described.

According to an embodiment, the source diffusion barrier film 330 may be formed by a chemical vapor deposition (CVD) method, a physical vapor deposition (PVD) method, an atomic layer deposition (ALD) method, a thermal diffusion method, or an ion implantation method.

In an example case in which the source diffusion barrier film 330 includes a conductive material, the source diffusion barrier film 330 may be formed by the CVD method, the PVD method, or the ALD method.

In an example case in which the source diffusion barrier film 330 includes an insulating material, the source diffusion barrier film 330 may be formed by the CVD method, the PVD method, the ALD method, the thermal diffusion method, or the ion implantation method.

In an example case in which the source diffusion barrier film 330 is formed by the CVD method, first, precursor gas required for forming the source diffusion barrier film 330 is supplied to a reaction chamber. The precursor may be an element or compound of a material to form the source diffusion barrier film 330. Thereafter, the body 310 is prepared in the reaction chamber. Here, the body 310 may have undergone a heat treatment or a plasma treatment to promote a formation reaction of the source diffusion barrier film 330. Next, a reaction gas is injected into the reaction chamber to react with the precursor provided on the body 310. Through the above process, the source diffusion barrier film 330 may be formed on a surface of the body 310.

In an example case in which the source diffusion barrier film 330 is formed by the PVD method, first, a material to form the source diffusion barrier film 330 is prepared as a target. Thereafter, an inert gas such as argon (Ar) with high energy is injected into a vacuum chamber to generate plasma, and the plasma is collided with the target to generate source particles to be deposited on the source diffusion barrier film 330. Next, the source particles may be condensed on the surface of the body 310 to form the source diffusion barrier film 330.

In an example case in which the source diffusion barrier film 330 is formed by the ALD method, first, the body 310 whose surface is cleaned is prepared. Thereafter, a primary precursor gas required for forming the source diffusion barrier film 330 is injected into a reaction chamber. The primary precursor may be an element or compound of a material to form the source diffusion barrier film 330. The primary precursor may be, for example, AlCl₃. The injected primary precursor gas may be adsorbed on the surface of the body 310, and the adsorbed primary precursor may primarily form a chemical bond by bonding with atoms forming the surface of the body 310. After the primary precursor is adsorbed, the reaction chamber may be cleaned. In this case, the residues of the unnecessary primary precursor gas may be removed by injecting an inert gas.

Next, a secondary precursor is injected into the reaction chamber. The secondary precursor may be oxygen, nitrogen, or a compound different from the primary precursor. The secondary precursor may be, for example, water (H₂O).

The secondary precursor may react with the primary precursor adsorbed on the surface of the body 310 to form a solid-state thin film. The thin film may form a portion of the source diffusion barrier film 330. In an example case in which the primary precursor is AlCl₃, water (H₂O) may be injected as the secondary precursor to react with aluminum (Al) of the primary precursor to form a solid-state aluminum oxide (Al₂O₃). The above process may be repeated to form the source diffusion barrier film 330.

In an example case in which the source diffusion barrier film 330 is formed by the ALD method, the thickness WD of the source diffusion barrier film 330 may range from 100 Å to 1000 Å. In one embodiment, the source diffusion barrier film 330 formed by the ALD method may have improved bonding strength with body 310 and improved chemical resistance to a cleaning solution.

In an example case in which the source diffusion barrier film 330 is formed by the thermal diffusion method, first, the body 310 whose surface is cleaned is prepared.

Thereafter, a source material to form the source diffusion barrier film 330 is provided on the surface of the body 310. The source material may be, for example, a metal oxide, a metal sulfide, a metal fluoride, or a metal nitride. Thereafter, the body 310 and the source material are heated to a predetermined temperature. In this case, the heating temperature may vary depending on the characteristics of the source material and a thickness of the source diffusion barrier film 330 to be formed. For example, the heating temperature may range from 300° C. to 1000° C. The source material may diffuse into the surface of the body 310 through heating, and atoms of the source material may be bound with atoms of the body 310 to form a thin film. Thereafter, a stabilization step of the thin film through cooling may be performed, and finally, the source diffusion barrier film 330 may be formed on the surface of the body 310.

In an example case in which the source diffusion barrier film 330 is formed by the thermal diffusion method, a concentration of the atoms of the source material of the source diffusion barrier film 330 may be uniform depending on a depth of the source diffusion barrier film 330.

According to an embodiment, the source diffusion barrier film 330 may be formed using the ion implantation method.

In an example case in which the source diffusion barrier film 330 is formed by the ion implantation method, first, the body 310 whose surface is cleaned is prepared. Thereafter, an impurity implantation device is prepared, and the type and energy of an impurity to be implanted are set. The impurity may be, for example, oxygen ions, nitrogen ions, sulfur ions, or fluorine ions.

Subsequently, the impurity generated by the impurity implantation device may be implanted into the surface of the body 310. In this case, a depth of implantation of the impurity may vary depending on the type and energy of the impurity. The impurity may penetrate a lattice structure in the body 310 to become some of materials that forms the source diffusion barrier film 330. The impurity penetrated into the body 310 may react with the atoms in the body 310 to form a new material and/or change the lattice structure. In an example case in which the body 310 includes aluminum, oxygen ions may penetrate the aluminum lattice structure in the body 310, and the oxygen ions may react with the aluminum to form an aluminum oxide (Al₂O₃). Thereafter, a diffusion reaction in the body 310 may be promoted through a thermal treatment. Through the above process, the source diffusion barrier film 330 may be formed from the surface of the body 310 to a predetermined depth.

In an example case in which the source diffusion barrier film 330 is formed by using the ion implantation method, the source diffusion barrier film 330 may be an insulating material. In addition, the body 310 may include the same metal as a metal included in the source diffusion barrier film 330. For example, the body 310 may include aluminum (Al), and the source diffusion barrier film 330 may include an aluminum oxide (Al₂O₃).

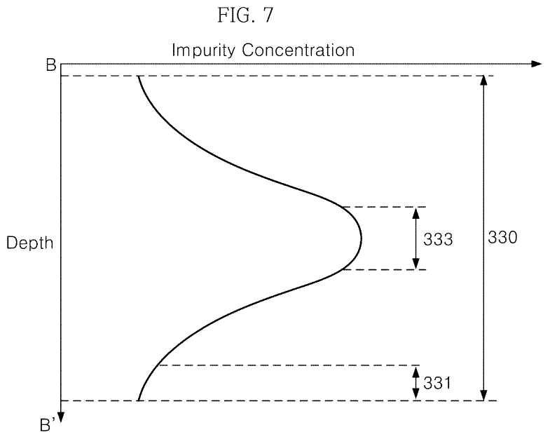

FIG. 7 is an impurity concentration graph corresponding to line B-B'of FIG. 6. For example, FIG. 7 is a graph showing an impurity ion concentration according to the depth of the source diffusion barrier film 330 in an example case in which the source diffusion barrier film 330 is formed through the ion implantation process. Here, a horizontal axis indicates the impurity concentration, and a vertical axis indicates the depth of the source diffusion barrier film.

Referring to FIGS. 6 and 7, the source diffusion barrier film 330 may include a lower portion 331 adjacent to the body 310 and an intermediate portion 333 spaced apart from the lower portion 331. In an example case in which the source diffusion barrier film 330 is formed by the ion implantation method that implants impurity ions into the body 310, the impurity concentration of the source diffusion barrier film 330 may vary depending on the depth of the source diffusion barrier film 330. For example, as shown in the graph of FIG. 7, the impurity concentration may decrease toward a portion adjacent to the body 310. For example, the impurity concentration of the intermediate portion 333 of the source diffusion barrier film may be higher than the impurity concentration of the lower portion 331 of the source diffusion barrier film 330. Similarly, the impurity concentration of an upper portion, which is a portion adjacent to an outer surface of the source diffusion barrier film 330, may be smaller than the impurity concentration of the intermediate portion 333 of the source diffusion barrier film 330. For example, the impurity concentration of the source diffusion barrier film 330 may be unevenly distributed in a depth direction of the source diffusion barrier film 33.

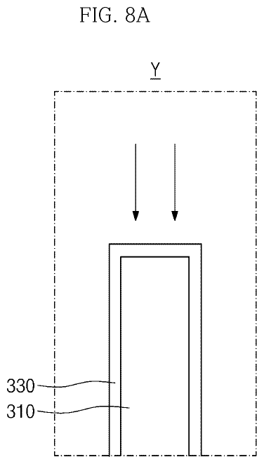

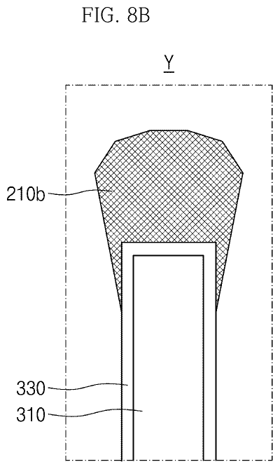

FIGS. 8A and 8B are enlarged views showing a portion of the collimator according to an embodiment of the disclosure and enlarged views corresponding to region Y of FIG. 4. For example, FIGS. 8A and 8B show processes in which source particles generated from the target 200 are prevented from diffusing into the body 310 by the source diffusion barrier film 330.

Referring to FIG. 8A, when the deposition process is performed, the source particles may fall off from the target 200 (refer to FIG. 1) by the plasma PL (refer to FIG. 1), and some of the source particles may not pass through the holes 350h of the collimator 300 and may be deposited on the source diffusion barrier film 330.

Referring to FIG. 8B, some of the source particles may be deposited on the source diffusion barrier film 330 to form deposits 210b. After the deposition process is completed, a cleaning process may be performed to reuse the collimator 300 (refer to FIG. 1). The cleaning process may be performed through a separate cleaning solution. The cleaning solution may selectively remove the deposits 210b. In this case, the body 310 may be protected from the cleaning solution by the source diffusion barrier film 330. The above process may be repeated to repeatedly reuse the collimator 300 (refer to FIG. 1).

An embodiment of the disclosure can provide a substrate processing apparatus with improved damage to a base material and deposition precision.

Although the example embodiments of the disclosure have been described above, those skilled in the art or those having ordinary skill in the art will understand that various modifications and changes can be made to the inventive concept without departing from the spirit and technical scope of the present application as set forth in the claims described below.

Therefore, the technical scope of the disclosure should not be limited to the contents described in the detailed descriptions of the specification, but should be defined by the patent claims.

What is claimed is:

1. A substrate processing apparatus comprising:
a chamber;
a chuck provided in the chamber and configured to accommodate a substrate;
a plasma electrode provided in the chamber and vertically spaced apart from the chuck;
a target material provided on a lower surface of the plasma electrode; and
a collimator provided between the chuck and the target material, the collimator comprising:
a body comprising a plurality of holes; and
a source diffusion barrier film provided on a surface of the body and formed of a conductive material.

2. The substrate processing apparatus of claim 1, wherein the source diffusion barrier film comprises tantalum (Ta), a tantalum nitride (TaN), titanium (Ti), a titanium nitride (TiN), or a combination thereof.

3. The substrate processing apparatus of claim 1, wherein the body comprises aluminum (Al).

4. The substrate processing apparatus of claim 1, wherein the target material comprises copper (Cu).

5. The substrate processing apparatus of claim 1, wherein a thickness of the source diffusion barrier film ranges from 100 Å to 5500 Å.

6. The substrate processing apparatus of claim 1, further comprising:
a bias controller electrically connected to the collimator, the bias controller configured to apply a negative bias voltage to the source diffusion barrier film and the body.

7. The substrate processing apparatus of claim 1, wherein the source diffusion barrier film comprises a material having a body-centered cubic (BCC) structure or a hexagonal close-packed (HCP) structure.

8. The substrate processing apparatus of claim 1, wherein the source diffusion barrier film is formed by a chemical vapor deposition (CVD) method, a physical vapor deposition (PVD) method, or an atomic layer deposition (ALD) method.

9. A substrate processing apparatus comprising:
a chamber;
a chuck provided in the chamber and configured to accommodate a substrate;
a plasma electrode provided in the chamber and vertically spaced apart from the chuck;
a target material on a lower surface of the plasma electrode; and
a collimator between the chuck and the target material, the collimator comprising: a body comprising a plurality of holes; and
a source diffusion barrier film provided on a surface of the body and formed of an insulating material,
wherein a thickness of the source diffusion barrier film ranges from 100 Å to 5500 Å.

10. The substrate processing apparatus of claim 9, wherein the source diffusion barrier film comprises a metal oxide, a metal sulfide, a metal nitride, a metal fluoride, or a combination thereof.

11. The substrate processing apparatus of claim 10, wherein the body comprises a same metal as a metal included in the source diffusion barrier film.

12. The substrate processing apparatus of claim 11, wherein the body comprises aluminum (Al), and the source diffusion barrier film comprises an aluminum oxide (Al₂O₃).

13. The substrate processing apparatus of claim 9, wherein the source diffusion barrier film is formed by implanting impurity ions into the body.

14. The substrate processing apparatus of claim 13, wherein the source diffusion barrier film comprises a lower portion adjacent to the body and an intermediate portion spaced apart from the lower portion, and
wherein an impurity concentration of the intermediate portion of the source diffusion barrier film is higher than an impurity concentration of the lower portion of the source diffusion barrier film.

15. The substrate processing apparatus of claim 9, wherein the source diffusion barrier film is in an amorphous state.

16. A substrate processing apparatus comprising:
a chamber having an internal space;
a chuck provided in the internal space of the chamber;
a plasma electrode provided in the internal space of the chamber and spaced apart from the chuck;
a target material provided on a lower surface of the plasma electrode and including copper (Cu);
a support installed in an intermediate region of the internal space of the chamber; and
a collimator mounted on the support and provided between the chuck and the target material, the collimator comprising: a body comprises a plurality of holes, the body comprising aluminum (Al); and
a copper diffusion barrier film formed on a surface of the body.

17. The substrate processing apparatus of claim 16, further comprising:
a plasma position control module provided on a ceiling portion of the chamber.

18. The substrate processing apparatus of claim 16, wherein the copper diffusion barrier film is formed of a conductive material.

19. The substrate processing apparatus of claim 16, wherein the copper diffusion barrier film is formed of an insulating material.

20. The substrate processing apparatus of claim 16, wherein the copper diffusion barrier film comprises tantalum (Ta), a tantalum nitride (TaN), titanium (Ti), a titanium nitride (TiN), a metal oxide, a metal sulfide, a metal nitride, a metal fluoride, or a combination thereof.
